(19) United States
(12) Patent Application Publication
(10) Pub. No.: US 2017/0263722 A1
(43) Pub. Date: Sep. 14, 2017

(54) SEMICONDUCTOR DEVICE

(71) Applicant: SAMSUNG ELECTRONICS CO., LTD., Suwon-si (KR)

(72) Inventors: Jung Gun YOU, Ansan-si (KR); Gi Gwan PARK, Hwaseong-si (KR); Sug Hyun SUNG, Yongin-si (KR); Myung Yoon UM, Seoul (KR); Dong Suk SHIN, Yongin-si (KR)

(21) Appl. No.: 15/408,815

(22) Filed: Jan. 18, 2017

(30) Foreign Application Priority Data
Mar. 14, 2016 (KR) 10-2016-0030425
Apr. 26, 2016 (KR) 10-2016-0050728

(51) Int. Cl. H01L 29/417; H01L 27/088; H01L 29/78

(52) U.S. Cl. CPC H01L 29/41791; H01L 29/785; H01L 27/0886

(57) ABSTRACT

A semiconductor device includes a first gate electrode on a substrate, a first trench on a first side of the first gate electrode, a second trench on a second side of the first gate electrode, a depth of the second trench being greater than a depth of the first trench, a first source/drain filling the first trench, and a second source/drain filling the second trench, a height of an upper surface of the second source/drain being greater than a height of the first source/drain.

### CROSS-REFERENCE TO RELATED APPLICATION

Korean Patent Application Nos. 10-2016-0030425, filed on Mar. 14, 2016, and 10-2016-0050728 filed on Apr. 26, 2016, in the Korean Intellectual Property Office, and entitled: “Semiconductor Device,” are incorporated by reference herein in its entirety.

### BACKGROUND

1. Field

The present disclosure relates to a semiconductor device.

2. Description of the Related Art

As one of the scaling technologies to increase the density of semiconductor devices, the multi-gate transistor has been suggested, in which silicon bodies in a fin or nano wire shape are formed on a substrate, with gates formed on surfaces of the silicon bodies. Such a multi-gate transistor allows easy scaling, as it uses a three-dimensional channel. Further, current control capability can be enhanced without requiring increased gate length of the multi-gate transistor. Furthermore, it is possible to effectively suppress short channel effect (SCE) which is the phenomenon that the electric potential of the channel region is influenced by the drain voltage.

### SUMMARY

According to embodiments, there is provided a semiconductor device, including a substrate, a first gate electrode formed on the substrate, on the substrate, a first trench formed on one side of the first gate electrode, on the substrate, a second trench formed on the other side of the first gate electrode, wherein a depth of the second trench is greater than a depth of the first trench, a first source/drain filling the first trench and a second source/drain filling the second trench, wherein a height of an upper surface of the second source/drain is greater than a height of the first source/drain.

According to embodiments, there is also provided a semiconductor device, including a substrate, first and second gate electrodes formed on the substrate and formed in parallel each other, a first trench formed between the first and second gate electrodes, a second trench formed in the opposite direction from the first trench with reference to the first gate electrode, and having a different depth from that of the first trench, a third trench formed in the opposite direction from the first trench with reference to the second gate electrode, and having a same depth as that of the second trench, a first source/drain filling the first trench and second and third source/drains each filling the second and third source/drains, wherein a height of an upper surface of the second and third source/drains is different from a height of an upper surface of the first source/drain.

According to embodiments, there is also provided a semiconductor device, including a first gate electrode on a substrate, a first trench on a first side of the first gate electrode, a second trench on a second side of the first gate electrode, a first source/drain filling the first trench, and a second source/drain filling the second trench, the first and second source/drain having asymmetrical shapes with respect to an axis extending along the first gate electrode.

### BRIEF DESCRIPTION OF THE DRAWINGS

Features will become apparent to those of ordinary skill in the art by describing in detail exemplary embodiments with reference to the attached drawings, in which:

FIG. 1 illustrates a perspective view of a semiconductor device according to some exemplary embodiments;

FIG. 2 illustrates a partial perspective view provided to explain the substrate and fin-type patterns of FIG. 1;

FIG. 3 illustrates a layout diagram of the semiconductor device of FIG. 1;

FIG. 4 illustrates a cross sectional view taken along line A-A′ of FIG. 3;

FIG. 5 illustrates cross sectional views along lines B-B′ and C-C′ of FIG. 3;

FIG. 6 illustrates a cross sectional view along line D-D′ of FIG. 3;

FIG. 7 illustrates a cross sectional view of a semiconductor device according to some exemplary embodiments;

FIG. 8 illustrates a cross sectional view of a semiconductor device according to some exemplary embodiments;

FIG. 9 illustrates a cross sectional view of a semiconductor device according to some exemplary embodiments;

FIG. 10 illustrates cross sectional views of a semiconductor device according to some exemplary embodiments;

FIG. 11 illustrates a cross sectional view of a semiconductor device according to some exemplary embodiments;

FIG. 12 illustrates cross sectional views of a semiconductor device according to some exemplary embodiments;

FIG. 13 illustrates a cross sectional view of a semiconductor device according to some exemplary embodiments;

FIG. 14 illustrates cross sectional views of a semiconductor device according to some exemplary embodiments;

FIG. 15 illustrates cross sectional views of a semiconductor device according to some exemplary embodiments;

FIG. 16 illustrates a block diagram of an electronic system including a semiconductor device according to some exemplary embodiments; and

FIGS. 17 and 18 illustrate exemplary semiconductor systems including a semiconductor device according to some exemplary embodiments therein.

### DETAILED DESCRIPTION

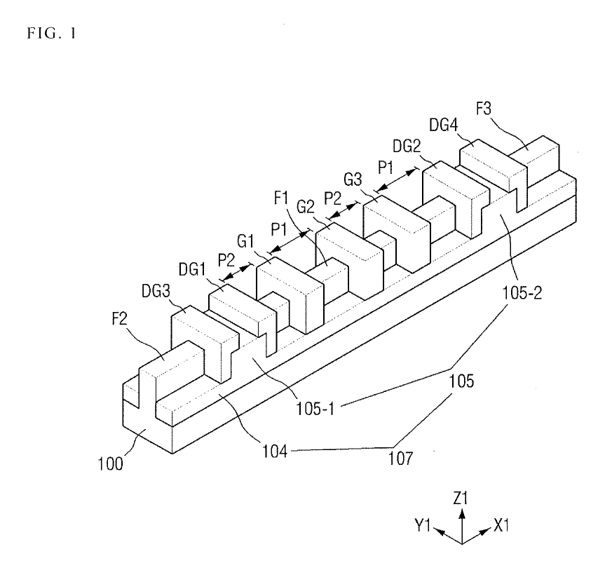

Hereinbelow, a semiconductor device according to some exemplary embodiments will be described with reference to FIGS. 1 to 6.

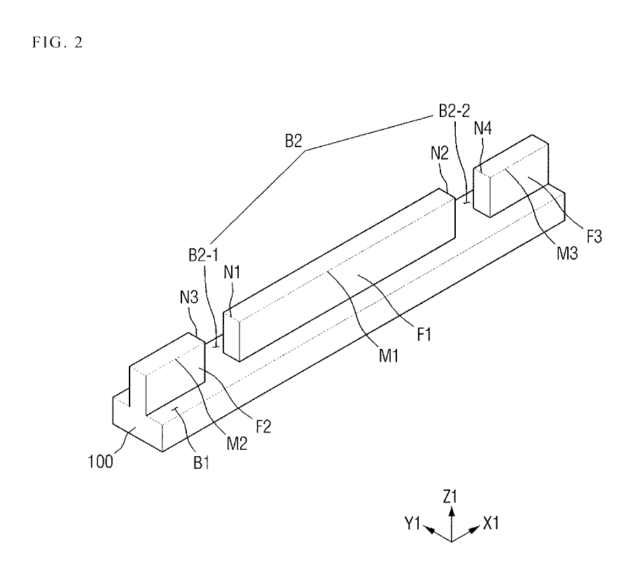

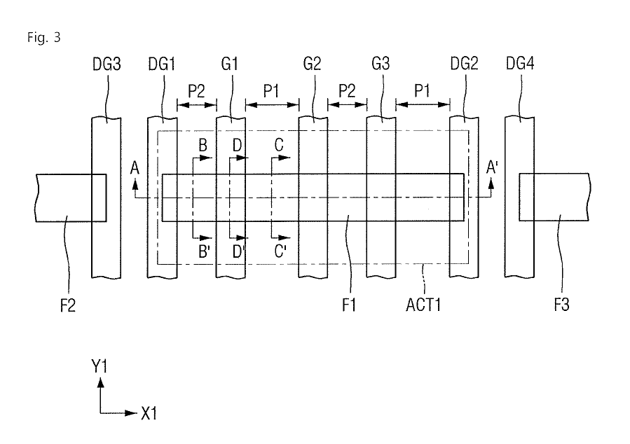

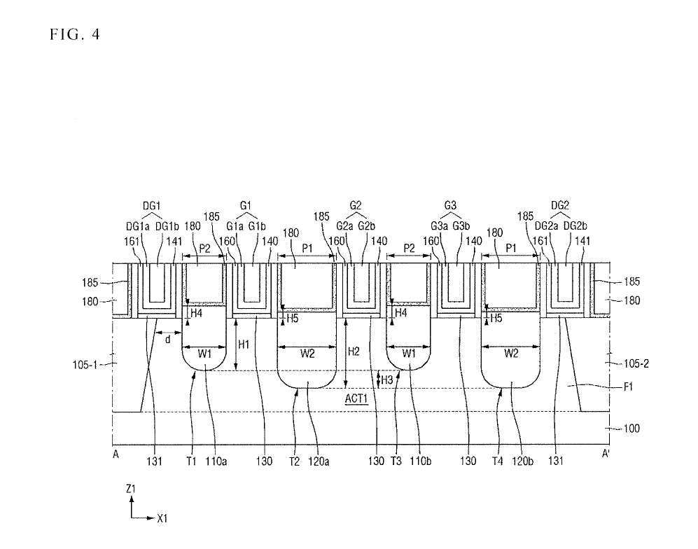

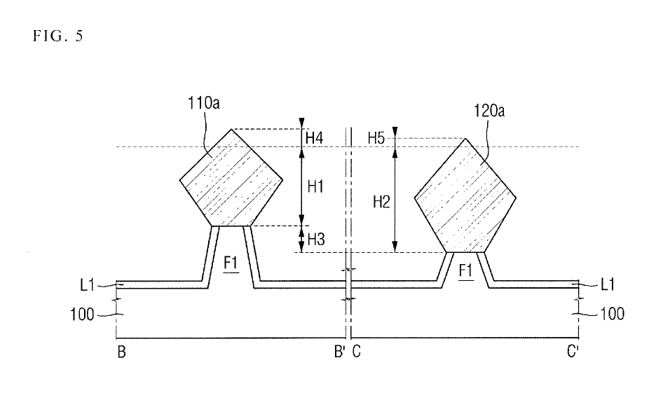

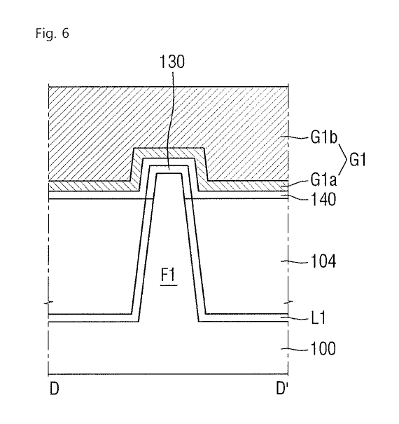

FIG. 1 is a perspective view of a semiconductor device according to some exemplary embodiments, and FIG. 2 is a partial perspective view of the substrate and fin-type patterns of FIG. 1. FIG. 3 is a layout diagram of the semiconductor device of FIG. 1, and FIG. 4 is a cross sectional view taken along line A-A′ of FIG. 3. FIG. 5 are cross sectional views taken along lines B-B′ and C-C′ of FIG. 3, and FIG. 6 is a cross sectional view along line D-D′ of FIG. 3. For convenience, illustration of an interlayer insulating film 180 and an etch-stop film 185 in FIG. 5 is eliminated.

Referring to FIGS. 1 to 6, a semiconductor device according to some exemplary embodiments may include a plurality of fin-type patterns F1-F3, a plurality of dummy gate electrodes DG1-DG4, first to third gate electrodes G1-G3, and so on.

The plurality of fin-type patterns F1-F3 may be elongated in a first direction X1. The fin-type patterns F1-F3 may be a portion of a substrate 100, and may include an epitaxial layer grown from the substrate 100. As exemplified in the drawings, three fin-type patterns F1-F3 may be formed parallel each other in a lengthwise direction, but exemplary embodiments are not limited thereto.

The first to third fin-type patterns F1-F3 may include, for example, an elemental semiconductor material, e.g., silicon or germanium. Further, the first to third fin-type patterns F1-F3 may include a compound semiconductor, e.g., IV-IV group compound semiconductor or III-V group compound semiconductor. For example, in the case of the IV-IV group compound semiconductor, the first fin-type pattern F1 may be a binary compound or a ternary compound including at least two or more of carbon (C), silicon (Si), germanium (Ge) or tin (Sn), or these compounds doped with IV group element. In another example, in the case of the III-V group compound semiconductor, the first fin-type pattern F1 may be one of a binary compound, a ternary compound or a quaternary compound which is formed by a combination of a III group element, e.g., at least one of aluminum (Al), gallium (Ga), or indium (In), with a V group element, e.g., at least one of phosphorus (P), arsenic (As) or antimony (Sb).

In some exemplary embodiments, the first to third fin-type patterns F1-F3 may be a nanowire structure having a stack of silicon and silicon germanium intersecting each other. However, in the following description, it is assumed that the first fin-type pattern F1 of a semiconductor device according to exemplary embodiments includes silicon.

As exemplified in the drawings, the fin-type patterns F1-F3 may be formed in a rectangular parallelepiped shape, but exemplary embodiments are not limited thereto. Accordingly, the fin-type patterns F1-F3 may be in a chamfered shape. That is, the fin-type patterns F1-F3 may be shaped such that the corners may be rounded. Since the fin-type patterns F1-F3 may be elongated in the first direction X1, they may include long sides M1-M3 formed in the first direction X1, and short sides N1-N4 formed in a second direction Y1. Specifically, the first fin-type pattern F1 may include a first short side N1, a second short side N2, and a first long side M1, and the second fin-type pattern F2 may include a third short side N3 and a second long side M2. The third fin-type pattern F3 may include a fourth short side N4 and a third long side M3.

As illustrated in FIGS. 1 and 2, the fin-type patterns F1-F3 may be formed in a rectangular parallelepiped shape, i.e., in a shape where the long sides M1-M3 of the fin-type patterns F1-F3 are vertically formed, although exemplary embodiments are not limited thereto. That is, as illustrated in FIGS. 5 and 6, the long sides M1-M3 of the tin-type patterns F1-F3 may be inclined. That is, a width of the fin-type patterns F1-F3 in the second direction Y1 may become greater in a downward direction, and become smaller in an upward direction.

As illustrated, the fin-type patterns F1-F3 may be formed such that the first short side N1 and the third short side N3 and the second short side N2 and the fourth short side N4 face each other. A person skilled in the art will be able to distinguish the long sides M1-M3 and the short sides N1-N4 even when the first to third fin-type patterns F1-F3 have rounded corners.

The fin-type patterns F1-F3 refer to active patterns used in a multi-gate transistor. Accordingly, the channels may be connected with each other along three surfaces of the fin-type patterns F1-F3, or alternatively, the channels may be formed on two facing surfaces of the fin-type patterns F1-F3.

Further, as illustrated in FIG. 2, the first fin trench B1 may be formed in contact with the long sides M1-M3 of the fin-type patterns F1-F3. The second fin trench B2 may be formed in contact with the short sides N1-N4 of the fin-type patterns F1-F3. In detail, the first fin trench B1 may be, e.g., continuously, formed on, e.g., along, side surfaces of the first to third fin-type patterns F1-F3. Further, the second fin trench B2 may be disposed between the short side N1 of the first fin-type pattern F1 and the short side N3 of the second fin-type pattern N2 that face each other, and between the short side N2 of the first fin-type pattern F1 and the short side N4 of the third fin-type pattern F3 that face each other.

In this case, the depth of the first fin trench B1 and the depth of the second fin trench B2 may be the same, but not limited thereto. This is because the first fin trench B1 and the second fin trench B2 are formed at the same time. However, when the first fin trench B1 and the second fin trench B2 are formed separately, each may have a different depth from the other.

As illustrated in FIG. 1, a field insulating film 107 may be formed on the substrate 100, and may surround at least of a portion of the plurality of fin-type patterns F1-F3. The field insulating film 107 may include a first portion 104 and a second portion 105.

The first portion 104 may be elongated in the first direction X1, and the second portion 105 may be elongated in the second direction Y1. For example, such field insulating film 107 may be an oxide film, a nitride film, an oxynitride film or a film combining these.

The first portion 104 is formed in at least a portion of the first fin trench B1, and the second portion 105 is formed in at least a portion of the second fin trench B2. In other words, the first portion 104 may be formed in contact with the long sides M1-M3 of the fin-type patterns F1-F3, and the second portion 105 may be formed in contact with the short sides N1-N4 of the fin-type patterns F1-F3. That is, since the second portion 105 may be formed between a second fin trench B2-1, i.e., a trench between the first fin-type pattern F1 and the second fin-type pattern F2, and a second fin trench B2-2, i.e., a trench between the first fin-type pattern F1 and the third fin-type pattern F3, the second portion 105 may be in contact, e.g., direct contact, with the sidewalls of the fin-type patterns F1-F3.

The first portion 104 may be formed in only a portion of the first fin trench B1. Further, the second portion 105 may, e.g., entirely, fill the second fin trench B2. As a result, an upper surface of the first portion 104 may be lower than an upper surface of the second portion 105 along the Z1 direction relative to a bottom of the substrate 100. In detail, the second portion 105 may include a portion 105-1 filling the second fin trench B2-1 and a portion 105-2 filling the second fin trench B2-2.

Further, a width of the second portion 105 may be wider than that of the first and second dummy gate electrodes DG1-DG4, e.g., a widest region of the second portion 105 along the X1 direction may be wider than that of each of the first and second dummy gate electrodes DG1-DG4. In this case, the width includes a width in the first direction X1.

The upper surface of the second portion 105 may be formed in the same plane as the upper surface of the adjacent fin-type patterns F1-F3, e.g., uppermost surfaces of the second portion 105 and the adjacent fin-type patterns F1-F3 may be level with each other. The term “formed in the same plane” as used herein allows and includes a margin of error caused by the process. Accordingly, a height of the first gate electrode G1 formed on the fin-type pattern, e.g., formed on the fin-type pattern F1, and a height of the dummy gate electrode, e.g., the dummy gate electrode DG1, formed on the second portion 105 and the first fin-type pattern F1 may be the same as each other. For example, upper surfaces of the first gate electrode G1 and the dummy gate electrode DG1, as measured from the bottom of the substrate 100, may be substantially level with each other due to the level upper surfaces of the second portion 105 and the fin-type patterns F1-F3. As such, the dispersion, e.g., variation, in heights of the plurality of dummy gate electrodes DG1-DG4 and the first gate electrode G1 may be significantly decreased.

As described above, the plurality of dummy gate electrodes DG1-DG4 and the first gate electrode G1 may be formed using polysilicon and metal, and operation characteristics of the plurality of dummy gate electrodes DG1-DG4 and the first gate electrode G1 may vary as their respective heights vary. However, when the dispersion in heights of the plurality of dummy gate electrodes DG1-DG4 and the first gate electrode G1 is small, operation characteristics may also be easily controlled in a certain range.

As illustrated in FIG. 3, the plurality of dummy gate electrodes DG1-DG4 and the first to third gate electrodes G1-G3 may be formed on the corresponding fin-type patterns F1-F3, while intersecting with the corresponding fin-type patterns F1-F3. For example, the first dummy gate electrode DG1, the second dummy gate electrode DG2, and the first to third gate electrodes G1-G3 may be formed on the first fin-type pattern F1, and the third dummy gate electrode DG3 may be formed on the second fin-type pattern F2. The fourth dummy gate electrode DG4 may be formed on the third fin-type pattern F3. Each dummy gate spacer 161 may be formed on both sides of the first dummy gate electrode DG1 and the second dummy gate electrode DG2 (FIG. 4).

Referring to FIG. 4, the substrate 100 may be formed of one or more semiconductor materials, e.g., Si, Ge, SiGe, GaP, GaAs, SiC, SiGeC, InAs and InP. Further, a silicon on insulator (SOI) substrate may be used.

As further illustrated in FIG. 4, the first gate electrode G1 may include metal layers G1a, G1b, e.g., the first gate electrode G1 may include a stack of two or more metal layers G1a and G1b. The first metal layer G1a adjusts a work function, and the second metal layer G1b fills a space defined by the first metal layer G1a. For example, the first metal layer G1a may include at least one of TiN, TaN, TiC, and TaC. Further, the second metal layer G1b may include W or Al.

The second gate electrode G2 may include metal layers G2a and G2b, e.g., the second gate electrode G2 may include a stack of two or more metal layers G2a and G2b. The first metal layer G2a adjusts a work function, and the second metal layer G2b fills a space defined by the first metal layer G2a. For example, the first metal layer G2a may include at least one of TiN. TaN, TiC, and TaC. Further, the second metal layer G2b may include W or Al.

The third gate electrode G3 may include metal layers G3a and G3b, e.g., the third gate electrode G3 may include a stack of two or more metal layers G3a and G3b. The first metal layer G3a adjusts a work function, and the second metal layer G3b fills a space defined by the first metal layer G3a. For example, the first metal film G3a may include at least one of TiN, TaN, TiC, and TaC. Further, the second metal layer G3b may include W or Al.

For example, the first to third gate electrodes G1-G3 described above may be formed by a replacement process (or gate last process), but not limited thereto. The first to third gate electrodes G1-G3 may be formed on the first fin-type pattern F1. In detail, as illustrated in FIG. 3, the first gate electrode G1 may be formed adjacent to a first end portion of the first fin-type pattern F1, i.e. adjacent to the first short side N1 of the first fin-type pattern F1. The third gate electrode G3 may be formed adjacent to a second end portion of the first fin-type pattern F1, i.e. adjacent to the second short side N2 of the first fin-type pattern F1. The second gate electrode G2 may be formed between the first gate electrode G1 and the second gate electrode G2.

As further illustrated in FIG. 3, a first pitch P1 may be formed, e.g., defined, between the first gate electrode G1 and the second gate electrode G2. A second pitch P2 may be formed, e.g., defined, between the second gate electrode G2 and the third gate electrode G3. The first pitch P1 may be greater than the second pitch P2. As illustrated in FIGS. 1 to 6, three gate electrodes may be formed, but this is provided only for illustrative purpose and exemplary embodiments are not limited thereto. Accordingly, the number of gate electrodes extending in parallel is not particularly limited.

Referring to FIGS. 1-2, two dummy gate electrodes, i.e., the first dummy gate electrode DG1 and the third dummy gate electrode DG3, may be formed between the first short side N1 of the first fin-type pattern F1 and the third short side N3 of the second fin-type pattern F2 that face each other. Similarly, two dummy gate electrodes, i.e., the second dummy gate electrode DG2 and the fourth dummy gate electrode DG4, may be formed between the second short side N2 of the first fin-type pattern F1 and the fourth short side N4 of the second fin-type pattern F3 that face each other.

The first dummy gate electrode DG1 may have a similar structure as the first to third gate electrodes G1-G3. As illustrated, the first dummy gate electrode DG1 may include a stack of two or more metal layers DG1a and DG1b. For example, the first dummy metal layer DG1a may adjust a work function, and the second metal layer DG1b may fill a space defined by the first dummy metal layer DG1a. The first dummy gate electrode DG1 may include a material substantially the same as the first to third gate electrodes G1-G3.

The second dummy gate electrode DG2 may have a similar structure as the first to third gate electrodes G1-G3 and as the first dummy gate electrode DG1. As illustrated, the second dummy gate electrode DG2 may include a stack of two or more metal layers DG2a and DG2b. For example, the first dummy metal layer DG2a may adjust a work function, and the second metal layer DG2b may fill a space defined by the first dummy metal layer DG2a. The second dummy gate electrode DG2 may include a material substantially the same as the first to third gate electrodes G1-G3.

The third dummy gate electrode DG3 and the fourth dummy gate electrode DG4 may also have the same two-layered structure as the first dummy gate electrode DG1, the second dummy gate electrode DG2, and the first to third gate electrodes G1-G3. That is, the first to third gate electrodes G1-G3 and the first to fourth dummy gate electrodes DG1-DG4 may all be formed by the same process.

The first dummy gate electrode DG1 may be formed on gate insulating films 131 and 141. The second dummy gate electrode DG2 may be formed on the gate insulating films 131 and 141. The first to third gate electrodes G1-G3 may be formed on gate insulating films 130 and 140.

The gate insulating films 130 and 140 may be formed between the first fin-type pattern F1 and the first gate electrode G1. As illustrated in FIG. 6, the gate insulating films 130 and 140 may be formed on the upper surface and on the upper portion of the side surface of the first fin-type pattern F1. Further, the gate insulating films 130 and 140 may be disposed between the first to third gate electrodes G1-G3 and the first portion 104.

The gate insulating films 131 and 141 may be formed between the first fin-type pattern F1 and the first dummy gate electrode DG1, and between the second portion 105-1 of the field insulating film 107 and the first dummy gate electrode DG1. The gate insulating films 131 and 141 may be formed between the first fin-type pattern F1 and the second dummy gate electrode DG2, and between the second portion 105-2 of the field insulating film 107 and the second dummy gate electrode DG2.

The gate insulating films 130, 140, 131 and 141 may include silicon oxide film and a high-k dielectric material with a higher dielectric constant than silicon oxide film. The gate insulating films 130, 140, 131 and 141 may include interfacial films 130 and 131 and high-k dielectric films 140 and 141.

The interfacial films 130 and 131 may be formed by partially oxidizing the first fin-type pattern F1. The interfacial films 130 and 131 may be formed along the profile of the first fin-type pattern F1 protruding upward further than the upper surface of the first portion 104. When the first fin-type pattern F1 is a silicon fin-type pattern including silicon, the interfacial films 130 and 131 may include a silicon oxide film.

As illustrated in FIG. 6, the interfacial films 130 and 131 may not be formed along the upper surface of the first portion 104, but exemplary embodiments are not limited thereto. Depending on methods of forming the interfacial films 130 and 131, the interfacial films 130 and 131 may be formed along the upper surface of the first portion 104. Alternatively, even when the first portion 104 includes silicon oxide, when the silicon oxide included in the first portion 104 has different properties from the silicon oxide film included in the interfacial films 130 and 131, the interfacial films 130 and 131 may be formed along the upper surface of the first portion 104.

The high-k dielectric films 140 and 141 may be formed between the interfacial films 130 and 131 and the first and second gate electrodes G1 and G2. It may be formed along the profile of the first fin-type pattern F1 protruding upward further than the upper surface of the first portion 104. Further, the high-k dielectric films 140 and 141 may be formed between the first and second gate electrodes G1, G2 and the first portion 104.

The high-k dielectric films 140 and 141 may include a high-k dielectric material having a higher dielectric constant than silicon oxide film. For example, the high-k dielectric films 140 and 141 may include one or more of silicon oxynitride, silicon nitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate, but not limited thereto.

The dummy gate spacer 161 may include at least one of silicon nitride (SiN), silicon oxynitride (SiON), silicon oxide (SiO₂), silicon oxycarbonitride (SiOCN), or a combination thereof. Further, each dummy gate spacer 161 may be formed on sidewalls of a plurality of dummy gate electrodes DG1-DG4.

The gate spacer 160 may include at least one of silicon nitride (SiN), silicon oxynitride (SiON), silicon oxide (SiO₂), silicon oxycarbonitride (SiOCN), or a combination thereof. Further, each gate spacer 160 may be formed on sidewalls of the first to third gate electrodes G1-G3.

As exemplified in the drawings, the gate spacer 160 and the dummy gate spacer 161 may each be a single film, but may also be multi-spacers in which a plurality of films are stacked. Shapes of the gate spacer 160 and the dummy gate spacer 161, and shapes of the multi-spacers forming the gate spacer 160 and the dummy gate spacer 161 may each be I- or L-shape, or a combination thereof depending on the fabrication process and purpose of use.

Referring to FIG. 4, the first gate electrode G1 may include first and second side surfaces that are opposite each other. A first trench T1 may be formed on the first side surface of the first gate electrode G1. Correspondingly, a second trench T2 may be formed on the second side surface of the first gate electrode G1. That is, the first trench T1 and the second trench T2 may be located in the opposite direction with reference to the first gate electrode G1, e.g., the first and second trenches T1 and T2 may be on opposite sides of the first gate electrode G1. In other words, the first gate electrode G1 may be located between the first trench T1 and the second trench T2. The first trench T1 may be located between the first gate electrode G1 and the first dummy gate electrode DG1.

The second trench T2 may be formed between the first gate electrode G1 and the second gate electrode G2. A third trench T3 may be formed on the side surface opposite to the second trench T2 with reference to the second gate electrode G2. That is, the second trench T2 and the third trench T3 may be located in the opposite direction with reference to the second gate electrode G2, e.g., the second and third trenches 12 and T3 may be on opposite sides of the second gate electrode G2. In other words, the second gate electrode G2 may be located between the second trench T2 and the third trench T3.

The third trench T3 may be formed between the second gate electrode G2 and the third gate electrode G3. A fourth trench T4 may be formed on the side surface opposite to the third trench T3 with reference to the third gate electrode G3. That is, the third trench T3 and the fourth trench T4 may be located in the opposite direction with reference to the third gate electrode G3, e.g., the third and fourth trenches T3 and T4 may be on opposite sides of the third gate electrode G3. In other words, the third gate electrode G3 may be located between the third trench T3 and the fourth trench T4. The fourth trench T4 may be located between the third gate electrode G3 and the second dummy gate electrode DG2.

The first to fourth trenches T1-T4 may be, e.g., in a U shape. That is, sidewalls of the first to fourth trenches T1-T4 may be flat with gradually decreasing width downward. However, exemplary embodiments are not limited to the example given above.

A depth of the first trench T1 may be different from that of the second trench T2. That is, the depth of the first trench T1 may be less than the depth of the second trench T2. That is, a distance H1 from the upper surface of the first fin-type pattern F1 to the lower surface of the first trench T1 may be less than a distance H2 from the upper surface of the first fin-type pattern F1 to the lower surface of the second trench T2. Accordingly, a distance H3 between the lower surface of the second trench T2 and the lower surface of the first trench T1 may be greater than 0.

A width W1 of the first trench T1 may also be different from a width W2 of the second trench T2. That is, a width of the first trench T1 may be less than that of the second trench T2. The width as used herein may refer to the width along the X1 direction at a same depth level.

A depth of the third trench T3 may be different from that of the fourth trench T4. That is, the depth of the third trench T3 may be less than that of the fourth trench T4. That is, the distance H1 from the upper surface of the first fin-type pattern F1 to the lower surface of the third trench T3 may be less than the distance H2 from the upper surface of the first fin-type pattern F1 to the lower surface of the fourth trench T4. Accordingly, the distance H3 from the lower of the fourth trench T4 and the lower surface of the third trench T3 may be greater than 0.

The width W1 of the third trench T3 may also be different from the width W2 of the fourth trench T4. That is, the width of the third trench T3 may be less than the width of the fourth trench T4. The width as used herein may refer to the width at a same depth level.

In this case, the depth of the first trench T1 and the depth of the third trench T3 may be substantially the same. The term “substantially the same” refers to being formed by the same process and it allows for and includes presence of minute stepped portions, e.g., margin of error caused during manufacturing. Further, the width W1 of the first trench T1 and the width W1 of the third trench T3 may be substantially the same. The term “substantially the same” refers to being formed by the same process and it allows for and includes presence of minute stepped portions, e.g., margin of error caused during manufacturing.

Further, the depth of the second trench T2 and the depth of the fourth trench T4 may be substantially the same. The term “substantially the same” refers to being formed by the same process and it is the concept that includes a presence of minute stepped portions. Further, the width W2 of the second trench T2 and the width W2 of the fourth trench T4 may be substantially the same. The term “substantially the same” refers to being formed by the same process and it is the concept that includes a presence of minute stepped portions.

The first trench T1 and the second trench T2 of the semiconductor device according to some exemplary embodiments may have an asymmetrical shape with reference to the first gate electrode G1. Further, the third trench T3 and the fourth trench T4 may have an asymmetrical shape with reference to the third gate electrode G3. Accordingly, the second trench T2 and the third trench T3 may also have an asymmetrical shape with reference to the second gate electrode G2. This is attributable to the fact that a pitch between the first to third gate electrodes G1-G3 may not be constant in the manufacturing process of a trench on the upper surface of the first fin-type pattern F1.

That is, the first gate electrode G1 and the second gate electrode G2 may be spaced apart by the first pitch P1, and the second gate electrode G2 and the third gate electrode G3 may be spaced apart by the pitch P2 that is different from the first pitch P1. That is, the first gate electrode G1 and the first dummy gate electrode DG1 may be spaced apart by the second pitch P2, and the third gate electrode G3 and the second dummy gate electrode DG2 may be spaced apart by the first pitch P1. For example, the first through third gate electrodes G1-G3 and the dummy gate electrodes on the first fin-type pattern F1 may be arranged with alternating first and second pitch P1 and P2.

The trenches formed by the etch process may be deeper and wider in the region where a pitch between the gate electrodes is wide, e.g., as compare to depth and width in regions with smaller pitch. Accordingly, the second trench T2 between the first gate electrode G1 and the second gate electrode G2, and the fourth trench T4 between the third gate electrode G3 and the second dummy gate electrode DG2 may be formed relatively deep and wide, e.g., as compared to the first and third trenches T1 and T3. The first trench T1 between the first dummy gate electrode DG1 and the first gate electrode G1, and the third trench T3 between the second gate electrode G2 and the third gate electrode G3 may be formed relatively shallow and narrow, e.g., as compared to the second and fourth trenches T2 and T4.

Such asymmetrical shapes may be periodically formed. That is, considering the first trench T1 and the second trench T2 as one set, and the third trench T3 and the fourth trench T4 as another set, it can be expressed as a periodically repeating asymmetrical shape, i.e., a periodically repeating asymmetrical set of two trenches. This is attributable to the fact that when forming the gate electrode using Double Patterning Technology (DPT) or Quadruple Patterning Technology (QPT) patterning, pitches of two adjacent patterns are different from each other, but pitches between pattern sets, each including two patterns, are equal to each other.

As further illustrated in FIG. 4, the first to fourth source/drains 110a, 120a, 110b and 120b may fill the first to fourth trenches T1-T4. That is, the first source/drain 110a may fill the first trench T1, the second source/drain 120a may fill the second trench T2, the third source/drain 110b may fill the third trench T3, and the fourth source/drain 120b may fill the fourth trench T4.

An outer circumference of the first to fourth source/drains 110a, 120a, 110b and 120b may have a variety of shapes. For example, the outer circumference of each of the first to fourth source/drains 110a, 120a, 110b and 120b may be in at least one of diamond, circle, or rectangle shapes. For example, FIG. 5 illustrates a diamond-shaped source/drain (or pentagon or hexagon shape).

When the semiconductor device according to an exemplary embodiment is a PMOS transistor in a first active region ACT1, the first to fourth source/drains 110a, 120a, 110b and 120b may include a compressive stress material. For example, the compressive stress material may be a material that has a higher lattice constant than Si, e.g., SiGe. For example, the compressive stress material can enhance mobility of the carrier in the channel region by exerting compressive stress on the first fin-type pattern F1.

When the semiconductor device according to an exemplary embodiment is an NMOS transistor in the first active region ACT1, the first to fourth source/drains 110a, 120a, 110b and 120b may include a tensile stress material. For example, when the first fin-type pattern F1 is silicon, the first to fourth source/drains 110a, 120a, 110b and 120b may be a material having a smaller lattice constant than the silicon, e.g., SiC, SiPC, SiP. For example, the tensile stress material can enhance mobility of the carrier in the channel region by exerting tensile stress on the first fin-type pattern F1.

The upper surface of the first source/drain 110a may be formed higher than the upper surface of the second source/drain 120a. The first source/drain 110a may completely fill the first trench T1, and furthermore may be formed higher than the upper surface of the first fin-type pattern F1. The upper surface of the first source/drain 110a may be formed higher than the upper surface of the first fin-type pattern F1 by a fourth height H4. The upper surface of the second source/drain 120a may be formed higher than the upper surface of the first fin-type pattern F1 by a fifth height H5. The fourth height H4 may be greater than the fifth height H5.

The upper surface of the third source/drain 110b may be formed higher than the upper surface of the fourth source/drain 120b. The third source/drain 110b may completely fill the third trench T3, and furthermore may be formed higher than the upper surface of the first fin-type pattern F1. The upper surface of the third source/drain 110b may be formed higher than the upper surface of the first fin-type pattern F1 by a fourth height H4. The upper surface of the fourth source/drain 120b may be formed higher than the upper surface of the first fin-type pattern F1 by a fifth height H5.

The upper surface of the first source/drain 110a and the upper surface of the third source/drain 110b may be substantially the same. The upper surface of the second source/drain 120a and the upper surface of the fourth source/drain 120b may be substantially the same. The term “substantially the same” as used herein refers to being formed in the same scale by the same process, e.g., to be substantially level with each other, and it includes a presence of minute stepped portions.

The first source/drain 110a may be spaced apart from the first short side N1 of the first fin-type pattern F1. In detail, the first source/drain 110a and the first short side N1 of the first fin-type pattern F1 may be spaced apart from each other by d.

The etch-stop film 185 may be formed on the first to fourth source/drains 110a, 120a, 110b and 120b, and the gate spacer 160 and the dummy gate spacer 161. For example, the etch-stop film 185 may include at least one of silicon nitride (SiN), silicon oxynitride (SiON), silicon oxide (SiO₂), silicon oxycarbonitride (SiOCN), silicon carbonitride (SiCN), and a combination thereof.

An interlayer insulating film 180 may be formed on the first to fourth source/drains 110a, 120a, 110b and 120b and the etch-stop film 185. Further, the interlayer insulating film 180 may be formed to surround the first to third gate electrodes G1-G3, the first dummy gate electrode DG1, and the second dummy gate electrode DG2.

As illustrated in FIG. 5, the first liner L1 may be formed on a side surface of the first fin-type pattern F1. The first liner L1 may be formed conformally along the profile of the surface of the side surface of the first fin-type pattern F1. Furthermore, the first liner L1 may be formed along the upper surface of the substrate 100.

The first liner L1 may be formed of a material that applies a first stress to a channel region of the first fin-type pattern F1. The first liner L1 may enhance carrier mobility in the channel region by introducing the first stress to the channel region of the first fin-type pattern F1. In some exemplary embodiments, when the channel region is an N-type channel region, the first liner L1 may be formed of a material that applies a tensile stress to the channel region. For example, the first liner L1 may be formed of silicon nitride (SiN), silicon oxynitride (SiON), silicon boronitride (SiBN), silicon carbide (SiC), SiC:H, SiCN, SiCN:H, SiOCN, SiOCN:H, silicon oxycarbide (SiOC), silicon dioxide (SiO₂), polysilicon, or a combination thereof. In some exemplary embodiments, the first liner L1 may have a thickness of approximately 10 Å to 100 Å.

The first liner L1 may be omitted in some exemplary embodiments. In some exemplary embodiments, the first liner L1 may be formed as a dual structure of a first film of native oxide layer, and a second film of silicon nitride (SiN), silicon oxynitride (SiON), silicon boronitride (SiBN), silicon carbide (SiC), SiC:H, SiCN, SiCN:H, SiOCN, SiOCN:H, silicon oxycarbide (SiOC), silicon dioxide (SiO₂), polysilicon, or a combination thereof.

In the semiconductor device according to some exemplary embodiments, the source/drain may be shaped such that the source/drain is formed repeatedly in two units according to a shape of the source/drain. That is, the source/drains formed on both sides of the gate electrode may have an asymmetrical shape from each other. The asymmetrical shape of the source/drain in the semiconductor device according to some exemplary embodiments may enhance the operating performance of the semiconductor device by decreasing the contact resistance, thereby increasing the current density as the source/drain on one side is relatively increased. That is, a facet, e.g., a side, of one of the source/drain may be adjusted such that the relatively decreasing source/drain, e.g., the smaller source/drain of the two asymmetrical source/drain, is not contacted with a short side, i.e. an end portion, of the fin-type pattern, thus enhancing the operating performance of the semiconductor device.

If an end portion of the fin-type patterns F1-F3 were to be in contact with a sidewall of one of the source/drain, the source/drain could cause damage to the precision of the operation of the semiconductor device. In contrast, in the semiconductor device according to some exemplary embodiments, the asymmetrical shape of the source/drain increases a distance between the source/drain and the end portion of the fin-type pattern, thereby preventing contact therebetween. As a result, it is possible to prevent severe damages to the shape of the sidewall of o the source/drain, e.g., which may be potentially caused by bonding of the end portion of the fin-type pattern with the sidewall of the source/drain if in contact. Furthermore, an enhancement of the resistance performance in the source/drain formed in the relatively larger size source/drain may be additionally obtained, thereby providing a faster and more precise semiconductor device.

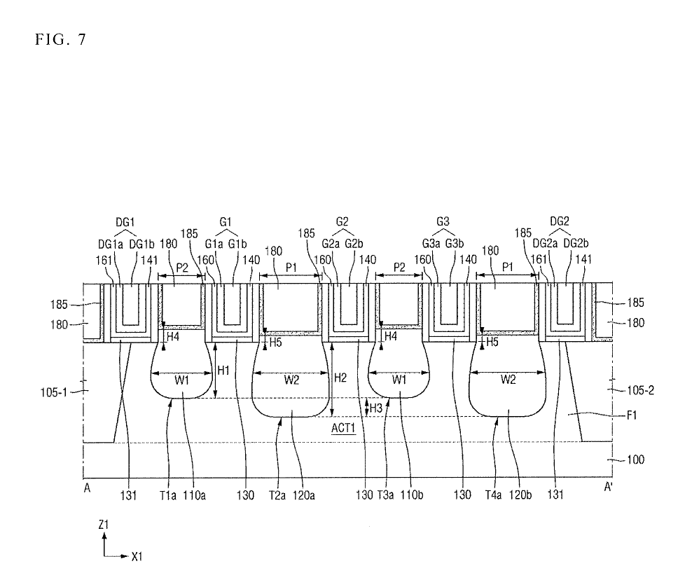

Hereinbelow, a semiconductor device according to some exemplary embodiments will be described with reference to FIGS. 3 and 7. In the following description, description overlapped with the exemplary embodiments already provided above will not be described or described as briefly as possible for the sake of brevity.

FIG. 7 is a cross sectional view of a semiconductor device according to some exemplary embodiments. FIG. 7 is a cross sectional view along line A-A′ of FIG. 3.

Referring to FIG. 7, the semiconductor device according to some exemplary embodiments may include first to fourth trenches T1a-T4a. Widths of the first to fourth trenches T1a-T4a may vary depending on depths. That is, the first to fourth trenches T1a-T4a may take a form in which the widths increase and then decrease as their depths increase. In detail, the change of the widths of the first to fourth trenches T1a-T4a may be caused by the etch process of inner portion of the fin-type patterns F1-F3. That is, etching of the first to fourth trenches T1a-T4a may be performed a plurality of times, rather than only once, thus leaving a shape in which the sidewalls of both sides become wider.

The second trench T2a and the fourth trench T4a may have better resistance characteristic as their widths increase. Although widths of the first trench T1a and the third trench T3a may be relatively smaller than the widths of the second trench T2a and the fourth trench T4a, the resistance characteristic thereof may be enhanced with increasing width, e.g., as compared to the first and second trenches T1 and T3 in FIGS. 1-6.

As such, as the widths of the first to fourth trenches T1a-T4a increase, a distance of the first source/drain 110a to the first short side N1, i.e., to an end portion of the first fin-type pattern F1, may be decreased. Accordingly, the shape of the first trench T1a with a relatively small first source/drain 110a may be more effective in order to secure a margin to prevent the first source/drain 110a from contacting with the end portion of the first fin-type pattern F1.

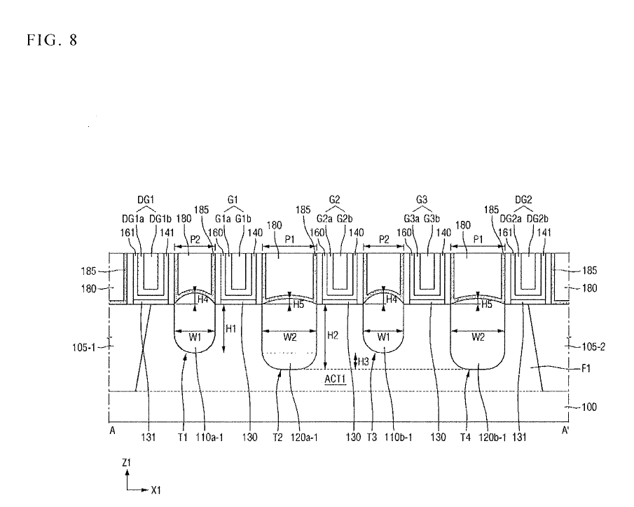

Hereinbelow, a semiconductor device according to some exemplary embodiments will be described with reference to FIGS. 3 and 8. In the following description, description overlapped with the exemplary embodiments already provided above will not be described or described as brief as possible for the sake of brevity.

FIG. 8 is a cross sectional view of a semiconductor device according to some exemplary embodiments. FIG. 8 is a cross sectional view along line A-A′ of FIG. 3.

Referring to FIG. 8, the semiconductor device according to some exemplary embodiments may include first to fourth source/drains 110a-1, 120a-1, 110b-1 and 120b-1. An upper surface of the first to fourth source/drains 110a-1, 120a-1, 110b-1 and 120b-1 may have an upwardly convex portion. That is, the upper surface of the first to fourth source/drains 110a-1, 120a-1, 110b-1 and 120b-1 may have a decreasing height with decreasing distance from the sidewall, and have an increasing height with increasing distance from the sidewall.

In detail, a height of the uppermost portion of each upper surface of the first to fourth source/drains 110a-1, 120a-1, 110b-1 and 120b-1 may be formed higher than the height of the first fin-type pattern F1 relative to the bottom of the substrate 100. That is, the height of the uppermost portion of the upper surface of the first source/drain 110a-1 may be formed higher than the height of the upper surface of the first fin-type pattern F1 by a fourth height H4. The height of the uppermost portion of the upper surface of the second source/drain 120a-1 may be formed higher than the height of the upper surface of the first fin-type pattern F1 by a fifth height H5. The height of the uppermost portion of the upper surface of the third source/drain 110b-1 may be formed higher than the height of the upper surface of the first fin-type pattern F1 by the fourth height H4. The height of the uppermost portion of the upper surface of the fourth source/drain 120b-1 may be formed greater than the height of the upper surface of the first fin-type pattern F1 by the fifth height H5. The fourth height H4 may be larger than the fifth height H5.

The etch-stop film 185 may be formed on the first to fourth source/drains 110a, 120a, 110b and 120b, and the gate spacer 160 and the dummy gate spacer 161. The etch-stop film 185 may have a concave lower portion, as the upper surface of the first to fourth source/drains 110a-1, 120a-1, 110b-1 and 120b-1 is convexly formed. That is, the etch-stop film 185 may be conformally formed along the upper surface of the first to fourth source/drains 110a-1, 120a-1, 110b-1 and 120b-1.

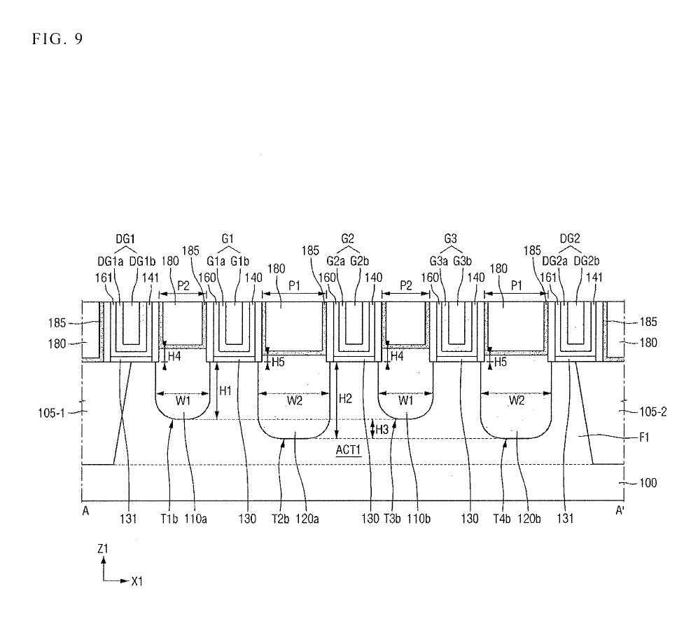

Hereinbelow, a semiconductor device according to some exemplary embodiments will be described with reference to FIGS. 3 and 9. In the following description, description overlapped with the exemplary embodiments already provided above will not be described or described as brief as possible for the sake of brevity.

FIG. 9 is a cross sectional view provided to explain a semiconductor device according to some exemplary embodiments. FIG. 9 is a cross sectional view taken along line A-A′ of FIG. 3.

Referring to FIG. 9, the semiconductor device according to some exemplary embodiments may include first to fourth trenches T1b-T4b. The first to fourth trenches T1b-T4b may be in contact with the lower portion of the dummy gate spacer 161 and the gate spacer 160. That is, sidewalls of the first to fourth trenches T1b-T4b may not be continuously connected with the sidewalls of the dummy gate spacer 161 and the gate spacer 160, but formed so as to expose the lower surface of the dummy gate spacer 161 and the gate spacer 160. This is attributable to the fact that the etch process to further widen the sidewall is added during etching.

The second trench T2b and the fourth trench T4b may have better resistance characteristic with increasing width. Although widths of the first trench T1b and the third trench T3b may be relatively smaller than the width of the second trench T2b and the fourth trench T4b, the resistance characteristic thereof may be improved with increasing width.

As such, as the widths of the first to fourth trenches T1b-T4b increase, a distance of the first source/drain 110a to the first short side N1, i.e., to a short portion of the first fin-type pattern F1, may be decreased. Accordingly, the shape of the first trench T1b with a relatively small first source/drain 110a can be more effective in order to secure a margin that can prevent the first source/drain 110a from contacting with the end portion of the first fin-type pattern F1.

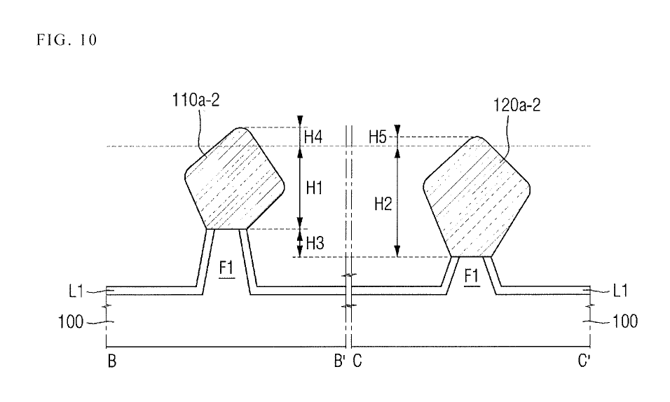

Hereinbelow, a semiconductor device according to some exemplary embodiments will be described with reference to FIGS. 3 and 10. In the following description, description overlapped with the exemplary embodiments already provided above will not be described or described as briefly as possible for the sake of brevity.

FIG. 10 is a cross sectional view of a semiconductor device according to some exemplary embodiments. FIG. 10 are cross sectional views along lines B-B′ and C-C′ of FIG. 3. For convenience of explanation, FIG. 10 skips illustration of the interlayer insulating film 180 and the etch-stop film 185.

Referring to FIG. 10, the semiconductor device according to some exemplary embodiments may include a first source/drain 110a-2 and a second source/drain 120a-2. Although not illustrated, the third source/drain 110b and the fourth source/drain 120b may also be similar to a shape of the first source/drains 110a-2 and the second source/drain 120a-2.

If the semiconductor device according to some exemplary embodiments is an NMOS device, the first source/drain 110a-2 and the second source/drain 120a-2 may include, e.g., Si, SiPC or SiP, and its epitaxial growth may not be carried out straightly in crystal orientation, unlike the SiGe. Accordingly, the first source/drain 110a-2 and the second source/drain 120a-2 may have a different shape from each other.

Further, the shape of each of the first source/drain 110a-2 and the second source/drain 120a-2 may be other than exact convex polygonal. That is, since the adjustment of the epitaxial growth may be influenced by several variables, each shape may represent approximately a convex polygon, e.g., a polygonal shape, but portions constituting the faces and lines can include any shape.

The semiconductor device according to some exemplary embodiments may enhance operating characteristic because even though it is difficult to control such shape of the source/drain, the end portion of the fin-type pattern is not contacted with the source/drain through an asymmetry of the trench.

Hereinbelow, a semiconductor device according to some exemplary embodiments will be described with reference to FIGS. 3, 11 and 12. In the following description, description overlapped with the exemplary embodiments already provided above will not be described or described as briefly as possible for the sake of brevity.

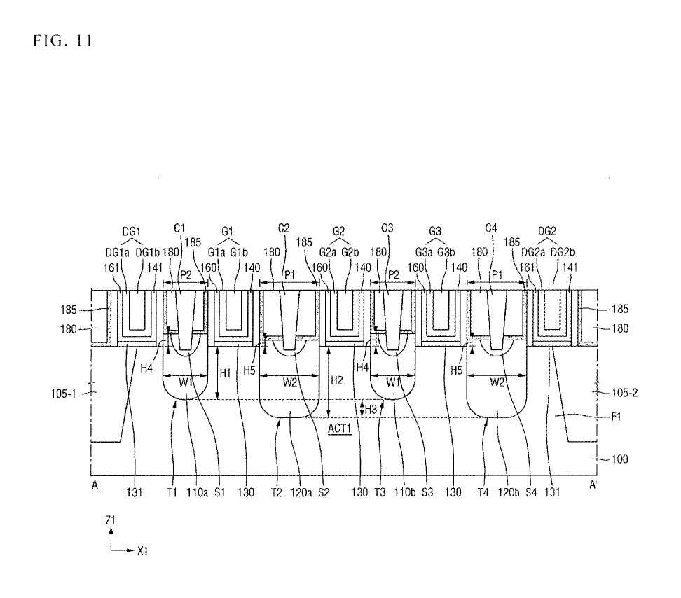

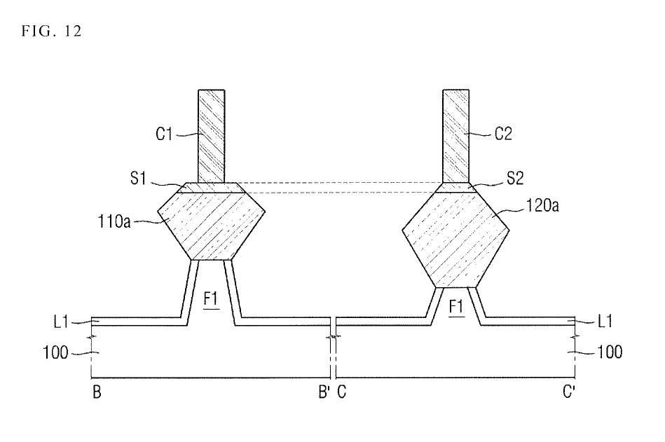

FIG. 11 illustrates cross sectional views of a semiconductor device according to some exemplary embodiments. FIG. 11 is a cross sectional view of a semiconductor device along line A-A′ of FIG. 3, and FIG. 12 illustrates cross sectional views taken along lines B-B′ and C-C′ of FIG. 3.

Referring to FIGS. 11 and 12, the semiconductor device according to some exemplary embodiments may include first to fourth contacts C1-C4 and first to fourth silicides S1-S4. The first to fourth silicides S1-S4 may be formed on the first to fourth source/drains 110a, 120a, 110b and 120b, respectively. The first to fourth silicides S1-S4 may be formed, as a portion of the first to fourth source/drains 110a, 120a, 110b and 120b is modified. The first to fourth silicides S1-S4 may include a metal. The metal may include at least one of, e.g., Ni, Co, Pt, Ti, W, Hf, Yb, Tb, Dy, Er, Pd, and a metal alloy thereof.

As illustrated, the first to fourth silicides S1-S4 may have a reversed cone type. Accordingly, a narrow tip region may be positioned downward (toward the substrate 100), and the bottom surface may be positioned upward (opposite direction to the substrate 100). Further, since the first to fourth silicides S1 and S4 have a structure in which the lower portion is narrow and becomes wider as it goes upward, the side surface may be inclined to a predetermined angle. The predetermined angle may be, e.g., about 30° to about 70°, but not limited thereto, e.g., about 40° to about 60°.

Further, tip regions of the first to fourth silicides S1-S4 may be located higher than a surface of the substrate 100. By doing this, it is possible to achieve enough channel length of a transistor, and improve operating characteristic of the transistor.

The first to fourth contacts C1-C4 may be formed on the first to fourth source/drains 110a, 120a, 110b and 120b. Recesses may be formed in the first to fourth source/drains 110a, 120a, 110b and 120b, and then the first to fourth contacts C1-C4 may be formed to fill the same. The first to fourth contacts C1-C4 may be electrically connected with the first to fourth source/drains 110a, 120a, 110b and 120b, respectively. To enhance the resistance characteristic between the first to fourth source/drains 110a, 120a, 110b and 120b and the first to fourth contacts C1-C4, the first to fourth silicides S1-S4 may be formed. The first to fourth contacts C1-C4 may be formed through the interlayer insulating film 180 and the etch-stop film 185 located on the first to fourth source/drains 110a, 120a, 110b and 120b.

Widths of the first to fourth contacts C1-C4 in a second direction Y1 may be substantially same. The thicknesses of the first to fourth silicides S1-S4 may be the same as each other, but not limited thereto.

Hereinbelow, a semiconductor device according to some exemplary embodiments will be described with reference to FIGS. 3, 13 and 14. In the following description, description overlapped with the exemplary embodiments already provided above will not be described or described as briefly as possible for the sake of brevity.

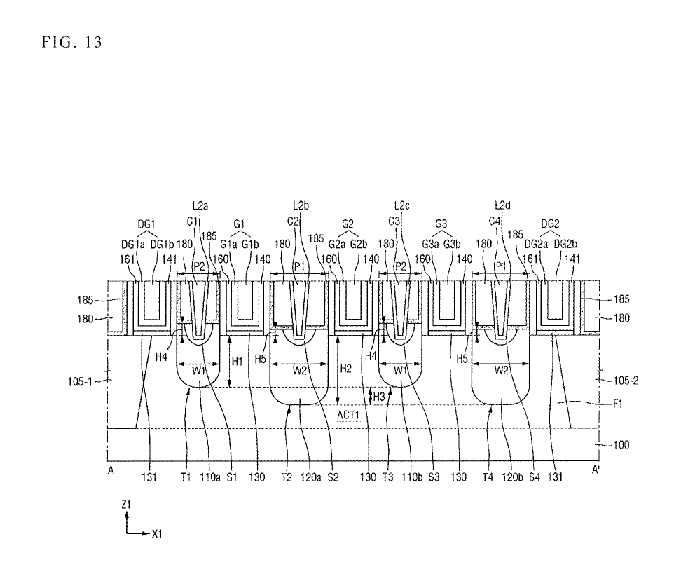

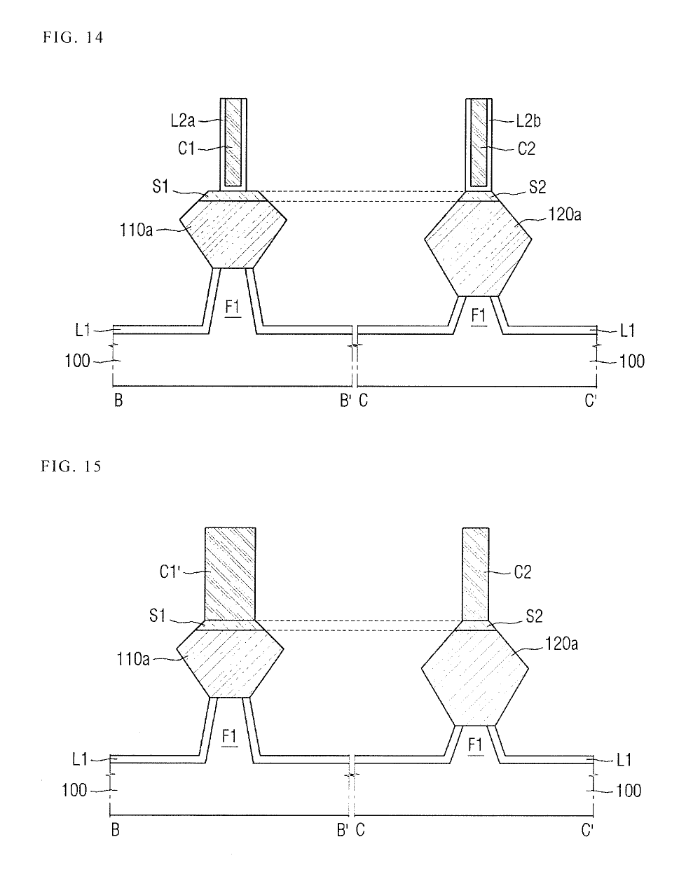

FIG. 13 is a cross sectional view of a semiconductor device according to some exemplary embodiments. FIG. 14 is a cross sectional view of the semiconductor device of FIG. 13. FIG. 13 is a cross sectional view taken along line A-A′ of FIG. 3. FIG. 14 illustrates cross sectional views taken along lines B-B′ and C-C′ of FIG. 3.

Referring to FIGS. 13 and 14, the semiconductor device according to some exemplary embodiments may additionally include first to fourth barrier layers L2a-L2d. The first to fourth barrier layers L2a-L2d may surround the surfaces of the first to fourth contacts C1-C4, respectively. The first to fourth barrier layers L2a-L2d may be conformally formed along a sidewall of the contact hole passing through the first to fourth silicides S1-S4, the etch-stop film 185 and the interlayer insulating film 180. The first to fourth contacts C1-C4 may be formed on the first to fourth barrier layers L2a-L2d, respectively.

The first to fourth barrier layer L2a-L2d may prevent parasitic capacitance between the first to fourth contacts C1-C4 and the interlayer insulating film 180, and facilitate the forming of the first to fourth contacts C1-C4.

Hereinbelow, a semiconductor device according to some exemplary embodiments will be described with reference to FIGS. 3, 11 and 15. In the following description, description overlapped with the exemplary embodiments already provided above will not be described or described as brief as possible for the sake of brevity.

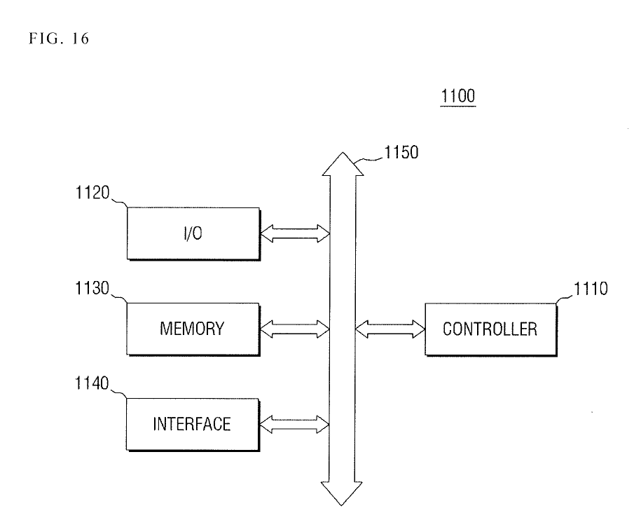

FIG. 15 is a cross sectional view of a semiconductor device according to some exemplary embodiments. FIG. 15 illustrates cross sectional views along lines B-B′ and C-C′ of FIG. 3.

Referring to FIGS. 11 and 15, the semiconductor device according to some exemplary embodiments may additionally include the first contact C1′ and the second contact C2 having different thicknesses in the second direction Y1.

The widths in the second direction Y1 of the upper surface of the first source/drain 110a and the second source/drain 120a may be different from each other. That is, the width in the second direction Y1 of the upper surface of the first source/drain 110a may be greater than the width in the second direction Y1 of the second source/drain 120a.

That is, the width in the second direction Y1 of the first contact C1′ may be the same as the width in the second direction Y1 of the upper surface of the first source/drain 110a. Further, the width in the second direction Y1 of the second contact C2 may be same as the width in the second direction Y1 of the upper surface of the second source/drain 120a. Accordingly, the width in the second direction Y1 of the first contact may be greater than the width in the second direction Y1 of the second contact C2 in the second direction Y1.

Accordingly, the semiconductor device according to some exemplary embodiments may have an enhanced resistance performance in the first contact. That is, the first contact may have lower resistance and higher current density as its width becomes wider. Accordingly, the semiconductor device can have faster speed and better precision.

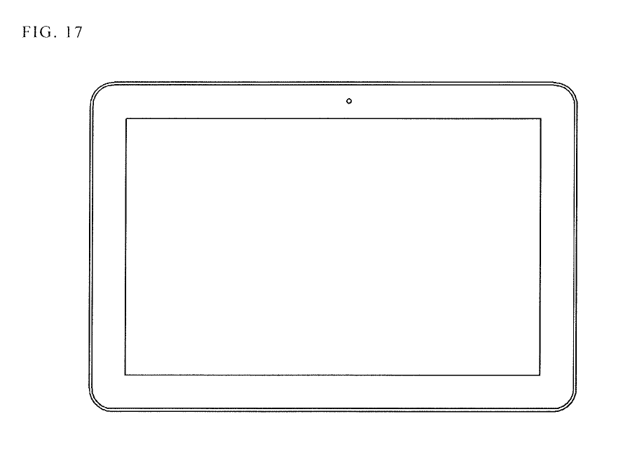

FIG. 16 is a block diagram of an electronic system including a semiconductor device according to some exemplary embodiments.

Referring to FIG. 16, the electronic system 1100 according to an exemplary embodiment may include a controller 1110, an input/output (I/O) device 1120, a memory device 1130, an interface 1140 and a bus 1150. The controller 1110, the I/O device 1120, the memory device 1130 and/or the interface 1140 may be connected with one another via the bus 1150. The bus 1150 corresponds to a path through which data travels.

The controller 1110 may include at least one of, e.g., microprocessor, digital signal process, micro controller, or logic devices capable of performing functions similar to the functions of those mentioned above. The I/O device 1120 may include, e.g., a keypad, a keyboard, a display device, and so on. The memory device 1130 may store data and/or instructions, and so on. The interface 1140 may perform a function of transmitting or receiving data to or from communication networks. The interface 1140 may be in a wired or wireless form. For example, the interface 1140 may include an antenna or a wired/wireless transceiver. The electronic system 1100 may additionally include an operation memory configured to enhance operation of the controller 1110, e.g., a high-speed dynamic random access memory (DRAM) and/or a static random access memory (SRAM). According to some exemplary embodiments, the semiconductor device may be provided within the memory device 1130, or provided as a part of the controller 1110, or the I/O device 1120.

The electronic system 1100 may be applicable to, e.g., a personal digital assistant (PDA) portable computer, a web tablet, a wireless phone, a mobile phone, a digital music player, a memory card, or almost all electronic products that are capable of transmitting and/or receiving data in wireless environment.

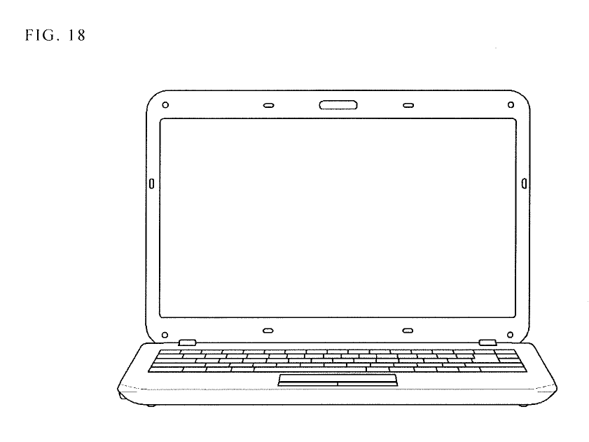

FIGS. 17 and 18 illustrate an exemplary semiconductor system which may apply a semiconductor device according to some exemplary embodiments therein. FIG. 17 illustrates a tablet PC and FIG. 18 illustrates a laptop computer. At least one of the semiconductor devices according to some exemplary embodiments may be used in the tablet PC, the laptop computer, and so on. It is apparent to those skilled in the art that the semiconductor device according to some exemplary embodiments is applicable to another integrated circuit device not illustrated herein.

By way of summation and review, embodiments provide a semiconductor device with improved operating characteristics. That is, a semiconductor device according to embodiments includes source/drain regions on opposite sides of a same gate electrode may be asymmetric, e.g., with different sizes (e.g., different depths, widths, volume, etc.) and/or different shapes, e.g., due to etching of the trenches for the source/drain regions at different pitches.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a first gate electrode on a substrate;
a first trench on a first side of the first gate electrode;
a second trench on a second side of the first gate electrode, a depth of the second trench being greater than a depth of the first trench;
a first source/drain filling the first trench; and
a second source/drain filling the second trench, a height of an upper surface of the second source/drain being greater than a height of the first source/drain.

2. The semiconductor device as claimed in claim 1, wherein the first and second trenches are U-shaped.

3. The semiconductor device as claimed in claim 1, wherein the first and second source/drains include a same material.

4. The semiconductor device as claimed in claim 1, further comprising:
a third trench in the opposite direction from the first trench with reference to the second trench;
a fourth trench in the opposite direction from the second trench with reference to the third trench;
a third source/drain filling the third trench; and
a fourth source/drain filling the fourth trench,
wherein:
depths of the first and third trenches are substantially the same,
depths of the second and fourth trenches are substantially the same,
upper surfaces of the first and third source/drains are substantially the same, and
upper surfaces of the second and fourth source/drains are substantially the same.

5. The semiconductor device as claimed in claim 4, wherein widths of the first and second trenches are the same, and widths of the second and fourth trenches are the same.

6. The semiconductor device as claimed in claim 4, further comprising a second gate electrode between the second source/drain and the third source/drain, and a third gate electrode between the third source/drain and the fourth source/drain.

7. The semiconductor device as claimed in claim 1, wherein a width of the first trench is less than a width of the second trench.

8. The semiconductor device as claimed in claim 1, further comprising a fin-type pattern protruding from the substrate, the fin-type pattern intersecting the first gate electrode under the first gate electrode,
wherein the first and second trenches, and the first and second source/drains are on the fin-type pattern.

9. A semiconductor device, comprising:
first and second gate electrodes on a substrate in parallel with each other;
a first trench between the first and second gate electrodes;
a second trench in the opposite direction from the first trench with reference to the first gate electrode, and having a different depth from that of the first trench;
a third trench in the opposite direction from the first trench with reference to the second gate electrode, and having a same depth as that of the second trench;
a first source/drain filling the first trench; and
second and third source/drains each filling the second and third source/drains, a height of an upper surface of the second and third source/drains being different from a height of an upper surface of the first source/drain.

10. The semiconductor device as claimed in claim 9, wherein a depth of the first and third trenches are less than a depth of the second trench.

11. The semiconductor device as claimed in claim 9, wherein:
the first and the second gate electrodes extend in a first direction, and
the semiconductor device further comprises a fin-type pattern extending in a second direction that intersects with the first direction, the first and the second gate electrodes being on the fin-type pattern.

12. The semiconductor device as claimed in claim 11, wherein:
the fin-type pattern includes a first end portion in the second direction more adjacent to the second trench than to the first and third trenches, and
the first end portion and the sidewall of the second trench are not in contact with each other.

13. The semiconductor device as claimed in claim 9, wherein the height of the upper surface of the second and third source/drains is greater than the height of an upper surface of the first source/drain.

14. The semiconductor device as claimed in claim 9, further comprising a first contact of a first width in contact with the first source/drain, and a second contact of a second width in contact with the second source/drain.

15. The semiconductor device as claimed in claim 14, wherein the first width and the second width are different from each other.

16. A semiconductor device, comprising:
a first gate electrode on a substrate;
a first trench on a first side of the first gate electrode;
a second trench on a second side of the first gate electrode;
a first source/drain filling the first trench; and
a second source/drain filling the second trench, the first and second source/drain having asymmetrical shapes with respect to an axis extending along the first gate electrode.

17. The semiconductor device as claimed in claim 16, wherein a height of an upper surface of the second source/drain is greater than a height of the first source/drain relative to a bottom of the substrate.

18. The semiconductor device as claimed in claim 16, further comprising a fin-type pattern on the substrate, the first gate electrode crossing the fin type pattern, and the first and second trenches are in the fin-type pattern.

19. The semiconductor device as claimed in claim 18, wherein an end portion of the fin type pattern and a sidewall of the first trench are spaced apart from each other, the sidewall of the first trench being adjacent to and facing the end portion of the fin type pattern.

20. The semiconductor device as claimed in claim 18, wherein the first trench is between the first gate electrode and an outermost surface of a lateral sidewall of the fin type pattern, a sidewall of the first trench facing the lateral sidewall of the fin type pattern and not contacting the lateral sidewall of the fin type pattern.
